(19) United States
(12) Patent Application Publication
(10) Pub. No.: US 2025/0126828 A1
(43) Pub. Date: Apr. 17, 2025

(54) SEMICONDUCTOR DEVICE AND MANUFACTURING METHOD THEREOF

(71) Applicant: NANYA TECHNOLOGY CORPORATION, New Taipei City (TW)

(72) Inventors: Yu-Ping Chen, New Taipei City (TW); Chen-Lun Ting, Taipei City (TW)

(73) Assignee: NANYA TECHNOLOGY CORPORATION, New Taipei City (TW)

(21) Appl. No.: 18/486,152

(22) Filed: Oct. 12, 2023

(51) Int. Cl. H01L 29/78; H01L 29/66

(52) U.S. Cl. CPC H10D 30/601; H10D 30/022

(57) ABSTRACT

Provided are a semiconductor device and a manufacturing method thereof. The semiconductor device includes a gate structure disposed on a substrate, source and drain regions, and first and second doped regions. The gate structure includes a gate disposed on the substrate, a gate dielectric layer disposed between the gate and the substrate, and a spacer disposed on sidewalls of the gate and the gate dielectric layer. The source and drain regions are disposed in the substrate and at two sides of the gate structure respectively. The first doped region is disposed in the substrate and adjacent to the source region. The second doped region is disposed in the substrate and located under the first doped region. The conductive type of the second doped region is opposite to that of the source region, the drain region and the first doped region.

### BACKGROUND

### Technical Field

The present invention relates to a semiconductor device and a manufacturing method thereof, and in particular to a semiconductor device having an asymmetric structure and a manufacturing method thereof.

### Description of Related Art

With the development of the semiconductor technology, the size of a semiconductor device continues to shrink. However, a semiconductor device with a smaller size may not be able to meet the electrical requirements.

A driving circuit having a larger size generally has a larger driving capability. Generally speaking, for improving the driving capability of the driving circuit, a transistor in the driving circuit may include a gate structure disposed on a substrate and including a gate disposed on the substrate, a gate dielectric layer disposed between the gate and the substrate and a spacer disposed on the sidewalls of the gate and the gate dielectric layer, a source region and a drain disposed in the substrate at both sides of the gate structure respectively, and lightly doped drain (LDD) regions and the pocket regions (or halo regions) are disposed in the substrate and adjacent to the source region and the drain region respectively. The reduction in the size of the transistor results in the reduction in the driving capability of the driving circuit. Therefore, how to maintain or even improve the performance of a semiconductor device under the condition of shrinking device size is an important issue.

### SUMMARY

The present invention provides a semiconductor device having an asymmetric structure and a manufacturing method thereof, in which an LDD region and a pocket region (or halo region) are formed in the substrate and only adjacent to the source region.

The semiconductor device of the present invention includes a gate structure disposed on a substrate, a source region, a drain region, a first doped region and a second doped region. The gate structure includes a gate disposed on the substrate, a gate dielectric layer disposed between the gate and the substrate, and a spacer disposed on sidewalls of the gate and the gate dielectric layer. The source region and the drain region are disposed in the substrate and at two sides of the gate structure respectively. The first doped region is disposed in the substrate and adjacent to the source region. The second doped region is disposed in the substrate and located under the first doped region. The source region, the drain region and the first doped region have a first conductive type, and the second doped region have a second conductive type opposite to the first conductive type. A doped concentration of the first doped region is less than doped concentrations of the source region and the drain region.

In an embodiment of the semiconductor device of the present invention, a depth of the drain region is not greater than a depth of the source region.

In an embodiment of the semiconductor device of the present invention, the doped concentration of the source region and the drain region is between 10¹⁶ cm⁻³ and 10²³ cm⁻³.

In an embodiment of the semiconductor device of the present invention, the doped concentration of the first doped region is between 10¹⁶ cm⁻³ and 10²³ cm⁻³.

In an embodiment of the semiconductor device of the present invention, the doped concentration of the second doped region is between 10¹⁶ cm⁻³ and 10²³ cm⁻³.

The manufacturing method of the semiconductor device of the present invention includes the following steps. A gate structure is formed on a substrate, wherein the gate structure includes a gate formed on the substrate, a gate dielectric layer formed between the gate and the substrate, and a spacer formed on sidewalls of the gate and the gate dielectric layer. A source region and a drain region are formed in the substrate and at two sides of the gate structure respectively. A first doped region is formed in the substrate and adjacent to the source region. A second doped region is formed in the substrate and located under the first doped region. The source region, the drain region and the first doped region have a first conductive type, and the second doped region have a second conductive type opposite to the first conductive type. A doped concentration of the first doped region is less than doped concentrations of the source region and the drain region.

In an embodiment of the manufacturing method of the semiconductor device of the present invention, a depth of the drain region is not greater than a depth of the source region.

In an embodiment of the manufacturing method of the semiconductor device of the present invention, the doped concentration of the source region and the drain region is between 10¹⁶ cm⁻³ and 10²³ cm⁻³.

In an embodiment of the manufacturing method of the semiconductor device of the present invention, the doped concentration of the first doped region is between 10¹⁶ cm⁻³ and 10²³ cm⁻³.

In an embodiment of the manufacturing method of the semiconductor device of the present invention, the doped concentration of the second doped region is between 10¹⁶ cm⁻³ and 10²³ cm⁻³.

Based on the above, in the present invention, the semiconductor device has an asymmetric structure in which the first doped region used as the LDD region and the second doped region used as the pocket region (or halo region) are only located at the source side. Therefore, the semiconductor device may have improved performance, such as higher current between the source and the drain (Ids), lower current leakage and prevention of drain induced barrier lowering (DIBL).

### BRIEF DESCRIPTION OF THE DRAWINGS

FIGS. 1A to 1D are schematic cross-sectional views of the manufacturing method of the semiconductor device of the first embodiment of the present invention.

FIG. 2 is a graph showing the relationship between the Ids and the leakage current of the semiconductor devices of the embodiment of the present invention and the comparative example.

FIG. 3 is another graph showing the relationship between the Ids and the leakage current of the semiconductor devices of the embodiment of the present invention and the comparative example.

FIG. 4 is a schematic cross-sectional view of the semiconductor device of the second embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

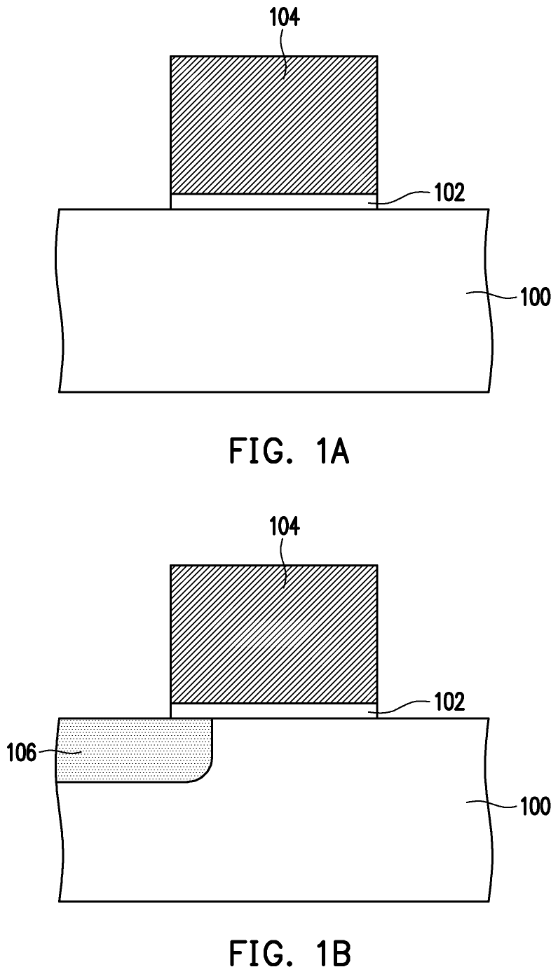

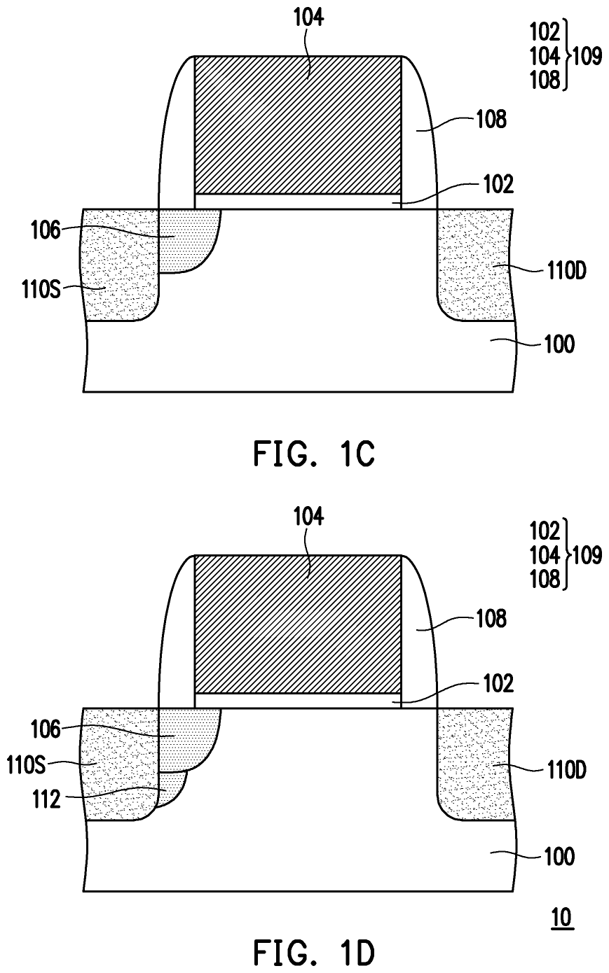

FIGS. 1A to 1D are schematic cross-sectional views of the manufacturing method of the semiconductor device of the first embodiment of the present invention.

Referring to FIG. 1A, a substrate 100 is provided. In the present embodiment, the substrate 100 is a silicon substrate, but the present invention is not limited thereto. In other embodiments, the substrate 100 may be a silicon-on-insulator (SOI) substrate. Next, a gate dielectric layer 102 and a gate 104 are formed on the substrate 100. In the present embodiment, a material of the gate dielectric layer 102 is oxide, and a material of the gate 104 is polysilicon, but the present invention is not limited thereto. In the present embodiment, a forming method of the gate dielectric layer 102 and the gate 104 may include the following steps. A gate dielectric material layer and a gate material layer are sequentially formed on the substrate 100. Then, a patterning process is performed on the gate dielectric material layer and the gate material layer to form the gate dielectric layer 102 and the gate 104.

Referring to FIG. 1B, a first doped region 106 is formed in the substrate 100 at one side of the gate 104. In the present embodiment, a forming method of the first doped region 106 is, for example, performing an ion implantation process. In the present embodiment, the first doped region 106 has a first conductive type, such as one of the n-type and the p-type. In the present embodiment, a doped concentration of the first doped region 106 is between 10¹⁶ cm⁻³ and 10²³ cm⁻³. The first doped region 106 may be used as an LDD region of the semiconductor of the present embodiment.

In addition, in the present embodiment, after forming the first doped region 106, a thermal process may be performed so that the dopants in the first doped region 106 may be diffused into a region under the gate 104, but the present invention is not limited thereto. In other words, in the present embodiment, the first doped region 106 may be extended under the gate 104. In other embodiments, a boundary of the first doped region 106 may be aligned with a sidewall of the gate 104.

Referring to FIG. 1C, a spacer 108 is formed on sidewalls of the gate 104 and the gate dielectric layer 102. In the present embodiment, a material of the space 108 is nitride, but the present invention is not limited thereto. In the present embodiment, a forming method of the spacer may include the following steps. A spacer material layer is conformally formed on the substrate 100. Then, an anisotropic etching process is performed to remove a part of the spacer material layer. In the present embodiment, the gate dielectric layer 102, the gate 104 and the spacer 108 form a gate structure 109.

Next, a source doped region 110S and a drain region 110D are formed in the substrate 100 at two sides of the gate structure 109. In the present embodiment, a forming method of the source doped region 110S and the drain region 110D is, for example, performing an ion implantation process using the gate structure 109 as a mask. In the present embodiment, the source doped region 110S and the drain region 110D have the first conductive type. In the present embodiment, the source doped region 110S and the drain region 110D have the same depth, and the depth of the source doped region 110S and the drain region 110D is greater than the depth of the first doped region 106. In the present embodiment, a doped concentration of the source doped region 110S and the drain region 110D is between 10¹⁶ cm⁻³ and 10²³ cm⁻³. The doped concentration of the first doped region 106 is less than doped concentrations of the source region 110S and the drain region 110D.

Referring to FIG. 1D, a second doped region 112 is formed in the substrate 100 and located under the first doped region 106. A bottom of the second doped region 112 is not lower a bottom of the source region 110S. In the present embodiment, a forming method of the second doped region 112 is, for example, performing a tilted ion implantation process. In the present embodiment, the second doped region 112 has a second conductive type opposite to the first conductive type, such as another of the n-type and the p-type. In the present embodiment, a doped concentration of the second doped region 112 is between 10¹⁶ cm⁻³ and 10²³ cm⁻³. The second doped region 112 may be used as a pocket region (or halo region) of the semiconductor of the present embodiment. In this way, a semiconductor device 10 of the present embodiment is formed.

In the present embodiment, the semiconductor device 10 has an asymmetric structure. In detail, in the semiconductor device 10, the first doped region 106 used as the LDD region and the second doped region 112 used as the pocket region (or halo region) only located at the source side. There is no LDD region and the pocket region (or halo region) at the drain side. In this way, the semiconductor device 10 may have improved performance, such as higher Ids, lower current leakage and prevention of DIBL. The semiconductor device 10 may be applied in a core circuit.

The effects of the present invention will be described below with the semiconductor device 10 of the present embodiment and a comparative example in which both of the source side and the drain side are provided with the LDD region and the pocket region (or halo region).

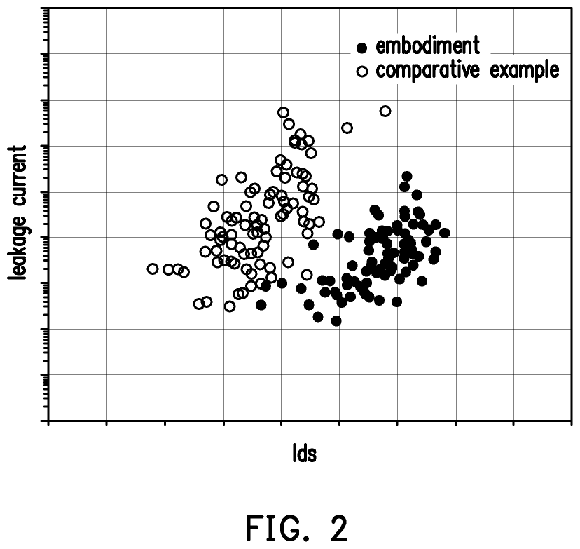

FIG. 2 is a graph showing the relationship between the current between the source and the Ids and the leakage current of the semiconductor devices of the embodiment of the present invention and the comparative example. Referring to FIG. 2, compared to the comparative example, the semiconductor device 10 of the present embodiment may have higher Ids without causing an increase in leakage current.

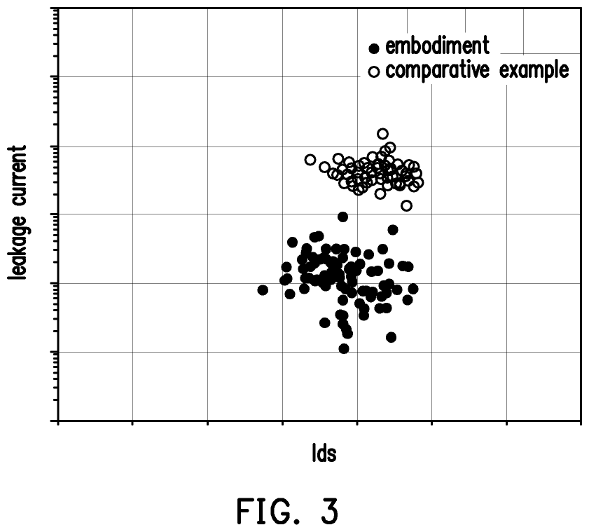

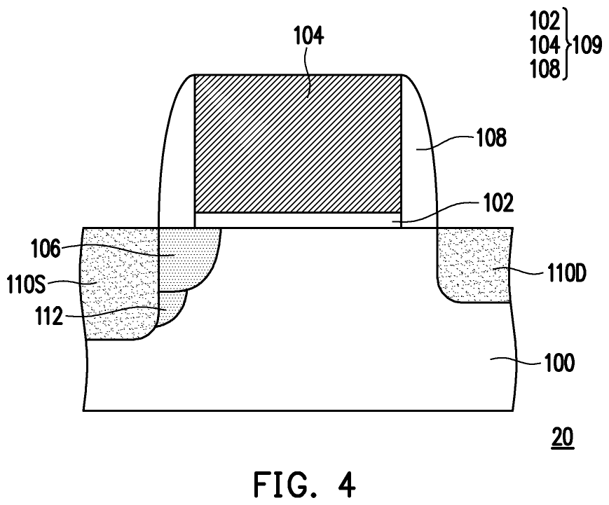

FIG. 3 is another graph showing the relationship between the Ids and the leakage current of the semiconductor devices of the embodiment of the present invention and the comparative example. Referring to FIG. 3, under the same Ids, compared to the comparative example, the semiconductor device 10 of the present embodiment may have lower current leakage.

In the semiconductor device 10 of the present embodiment, the source doped region 110S and the drain region 110D have the same depth, but the present invention is not limited thereto. In the present embodiment, the source doped region 110S and the drain region 110D have different depths.

FIG. 4 is a schematic cross-sectional view of the semiconductor device of the second embodiment of the present invention. In the present embodiment, the same device as that of the first embodiment will be denoted by the same reference symbols and will not be described again.

Referring to FIG. 4, in the semiconductor device 20, the depth of the drain region 110D is less than the depth of the source doped region 110S. Same as the semiconductor device 10 of the first embodiment, the semiconductor device 20 has an asymmetric structure in which the first doped region 106 used as the LDD region and the second doped region 112 used as the pocket region (or halo region) only located at the source side. Therefore, the semiconductor device 20 may have higher Ids, lower current leakage and prevention of DIBL. The semiconductor device 20 may be applied in a core circuit.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device, comprising:
a gate structure, disposed on a substrate, and comprising:
a gate, disposed on the substrate;
a gate dielectric layer, disposed between the gate and the substrate; and
a spacer, disposed on sidewalls of the gate and the gate dielectric layer;
a source region and a drain region, disposed in the substrate and at two sides of the gate structure respectively;
a first doped region, disposed in the substrate and adjacent to the source region; and
a second doped region, disposed in the substrate and located under the first doped region,
wherein the source region, the drain region and the first doped region have a first conductive type, and the second doped region have a second conductive type opposite to the first conductive type, and
wherein a doped concentration of the first doped region is less than doped concentrations of the source region and the drain region.

2. The semiconductor device of claim 1, wherein a depth of the drain region is not greater than a depth of the source region.

3. The semiconductor device of claim 1, wherein the doped concentrations of the source region and the drain region is between 10¹⁶ cm⁻³ and 10²³ cm⁻³.

4. The semiconductor device of claim 1, wherein the doped concentration of the first doped region is between 10¹⁶ cm⁻³ and 10²³ cm⁻³.

5. The semiconductor device of claim 1, wherein a doped concentration of the second doped region is between 10¹⁶ cm⁻³ and 10²³ cm⁻³.

6. A manufacturing method of a semiconductor device, comprising:
forming a gate structure on a substrate, wherein the gate structure comprises a gate formed on the substrate, a gate dielectric layer formed between the gate and the substrate, and a spacer formed on sidewalls of the gate and the gate dielectric layer;
forming a source region and a drain region in the substrate and at two sides of the gate structure respectively;
forming a first doped region in the substrate and adjacent to the source region; and
forming a second doped region in the substrate and located under the first doped region,
wherein the source region, the drain region and the first doped region have a first conductive type, and the second doped region have a second conductive type opposite to the first conductive type, and
wherein a doped concentration of the first doped region is less than doped concentrations of the source region and the drain region.

7. The manufacturing method of claim 6, wherein a depth of the drain region is not greater than a depth of the source region.

8. The manufacturing method of claim 6, wherein the doped concentrations of the source region and the drain region is between 10¹⁶ cm⁻³ and 10²³ cm⁻³.

9. The manufacturing method of claim 6, wherein the doped concentration of the first doped region is between 10¹⁶ cm⁻³ and 10²³ cm⁻³.

10. The manufacturing method of claim 6, wherein a doped concentration of the second doped region is between 10¹⁶ cm⁻³ and 10²³ cm⁻³.
